(19) United States
(12) Patent Application Publication
(10) Pub. No.: US 2022/0078944 A1
(43) Pub. Date: Mar. 10, 2022

(54) COMBINED HEAT-DISSIPATING STRUCTURE, ELECTRONIC APPARATUS CASING, AND ELECTRONIC APPARATUS

(71) Applicants: Inventec (Pudong) Technology Corp., Shanghai (CN); Inventec Corporation, Taipei (TW)

(72) Inventor: Hsiang-Yun Lu, Taipei (TW)

(21) Appl. No.: 17/117,132

(22) Filed: Dec. 10, 2020

(30) Foreign Application Priority Data
Sep. 8, 2020 (CN) 202010932112.6

(51) Int. Cl. H05K 7/20

(52) U.S. Cl. CPC H05K 7/20418; H05K 7/20436

(57) ABSTRACT

A combined heat-dissipating structure includes a main heat-dissipating structure and a detachable heat-dissipating structure. The main heat-dissipating structure has an opening, on which the detachable heat-dissipating structure is detachably disposed. A heat conduction column of the main heat-dissipating structure and a heat conduction column of the detachable heat-dissipating structure can be thermally coupled with different heat sources respectively. An electronic apparatus casing includes a casing base and the above combined heat-dissipating structure. The combined heat-dissipating structure and the casing base are connected to form an accommodating space. The combined heat-dissipating structure can dissipate heat from heat sources accommodated in the accommodating space. An electronic apparatus includes two heat sources and the above electronic apparatus casing. The two heat sources are accommodated in the accommodating space. The two heat conduction columns of the combined heat-dissipating structure are thermally coupled with the two heat sources respectively.

### BACKGROUND OF THE INVENTION

### 1. Field of the Invention

The present invention relates to a heat-dissipating structure, and more particularly to a combined heat-dissipating structure, an electronic apparatus casing having the combined heat-dissipating structure, and an electronic apparatus having the electronic apparatus casing.

### 2. Description of the Prior Art

Conventional heat dissipation structures used for electronic apparatus usually only dissipates heat from a single heat source. When there are multiple heat sources that need heat dissipation, multiple separate heat-dissipating structures need to be used to dissipate heat from the heat sources (e.g. chips) respectively. In some heat dissipation designs, the same heat-dissipating structure is used to dissipate heat from several heat sources at the same time. However, when the heat sources are far apart, the heat dissipation structure is not easy to maintain good thermal coupling with each heat source at the same time due to assembly tolerances (e.g. the assembly of the heat sources, the assembly of the heat dissipation structure, etc.), which affects the heat dissipation of the dissipation structure. When this situation is worse, poor contact between the heat dissipation structure and some of the heat sources, or excessive contact force applied to some of the heat sources probably occurs, leading to failure of the heat dissipation to the heat sources or structural damage. Furthermore, if the overall size of the heat dissipation structure is larger, the aforementioned problem will become much worse.

### SUMMARY OF THE INVENTION

An objective of the invention is to provide a combined heat-dissipating structure, which can dissipate heat from different heat sources through its separable structure.

A combined heat-dissipating structure according to the invention includes a main heat-dissipating structure and a detachable heat-dissipating structure. The main heat-dissipating structure includes a first plate portion, a first heat conduction column extending downward from the first plate portion, and a plurality of first fins extending upward from the first plate portion. The first plate portion has an opening. The first heat conduction column has a first heat-absorbing surface for absorbing heat produced by a heat source. The detachable heat-dissipating structure includes a second plate portion, a second heat conduction column extending downward from the second plate portion, and a plurality of second fins extending upward from the second plate portion. The second plate portion is detachably disposed at the opening. The second heat conduction column has a second heat-absorbing surface for absorbing heat produced by another heat source. Thereby, the main heat-dissipating structure and the detachable heat-dissipating structure can be structurally independently thermally coupled with the corresponding heat sources respectively, which can effectively solves the problem in the prior art that when a single heat-dissipating structure is used to dissipate heat from multiple heat sources, it is easy to cause poor contact or excessive contact force to cause heat dissipation failure or structural damage.

Another objective of the invention is to provide an electronic apparatus casing, which has one like the above combined heat-dissipating structure which can dissipate heat from different heat sources through its separable structure.

An electronic apparatus casing according to the invention includes a casing base and a combined heat-dissipating structure. The combined heat-dissipating structure and the casing base are connected to form an accommodating space. The combined heat-dissipating structure includes a main heat-dissipating structure and a detachable heat-dissipating structure. The main heat-dissipating structure is connected to the casing base. The main heat-dissipating structure includes a first plate portion, a first heat conduction column extending downward from the first plate portion, and a plurality of first fins extending upward from the first plate portion. The first plate portion has an opening. The first heat conduction column is located in the accommodating space and has a first heat-absorbing surface. The detachable heat-dissipating structure includes a second plate portion, a second heat conduction column extending downward from the second plate portion, and a plurality of second fins extending upward from the second plate portion. The second plate portion is detachably disposed at the opening. The second heat conduction column is located in the accommodating space and has a second heat-absorbing surface. Thereby, the first heat conduction column can be thermally coupled with a heat source disposed in the accommodating space through the first heat-absorbing surface to dissipate heat from the heat source; the second heat conduction column can be thermally coupled with another heat source disposed in the accommodating space through the second heat-absorbing surface to dissipate heat from the heat source. Because the main heat-dissipating structure and the detachable heat-dissipating structure can be structurally independently thermally coupled with the corresponding heat sources respectively, the problem in the prior art that when a single heat-dissipating structure is used to dissipate heat from multiple heat sources, it is easy to cause poor contact or excessive contact force to cause heat dissipation failure or structural damage can be effectively solved.

Another objective of the invention is to provide an electronic apparatus, which has one like the above electronic apparatus casing which has the combined heat-dissipating structure which can dissipate heat from different heat sources through its separable structure.

An electronic apparatus according to the invention includes a first heat source, a second heat source, and an electronic apparatus casing. The electronic apparatus casing includes a casing base and a combined heat-dissipating structure. The combined heat-dissipating structure and the casing base are connected to form an accommodating space. The first heat source and the second heat source are disposed in the accommodating space. The combined heat-dissipating structure includes a main heat-dissipating structure and a detachable heat-dissipating structure. The main heat-dissipating structure is connected to the casing base. The main heat-dissipating structure includes a first plate portion, a first heat conduction column extending downward from the first plate portion, and a plurality of first fins extending upward from the first plate portion. The first plate portion has an opening. The first heat conduction column is located in the accommodating space and has a first heat-absorbing surface. The first heat conduction column is thermally coupled with the first heat source through the first heat-absorbing surface. The detachable heat-dissipating structure includes a second plate portion, a second heat conduction column extending downward from the second plate portion, and a plurality of second fins extending upward from the second plate portion. The second plate portion is detachably disposed at the opening. The second heat conduction column is located in the accommodating space and has a second heat-absorbing surface. The second heat conduction column is thermally coupled with the second heat source through the second heat-absorbing surface. Thereby, the main heat-dissipating structure and the detachable heat-dissipating structure can be structurally independently thermally coupled with the corresponding heat sources respectively, which can effectively solves the problem in the prior art that when a single heat-dissipating structure is used to dissipate heat from multiple heat sources, it is easy to cause poor contact or excessive contact force to cause heat dissipation failure or structural damage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an electronic apparatus according to an embodiment.

FIG. 2 is a partially exploded view of the electronic apparatus in FIG. 1.

FIG. 3 is a schematic diagram illustrating a main heat-dissipating structure of a combined heat-dissipating structure in FIG. 2 in another view point.

FIG. 4 is a schematic diagram illustrating a detachable heat-dissipating structure of a combined heat-dissipating structure in FIG. 2 in another view point.

FIG. 5 is a sectional view of the electronic apparatus in FIG. 1.

### DETAILED DESCRIPTION

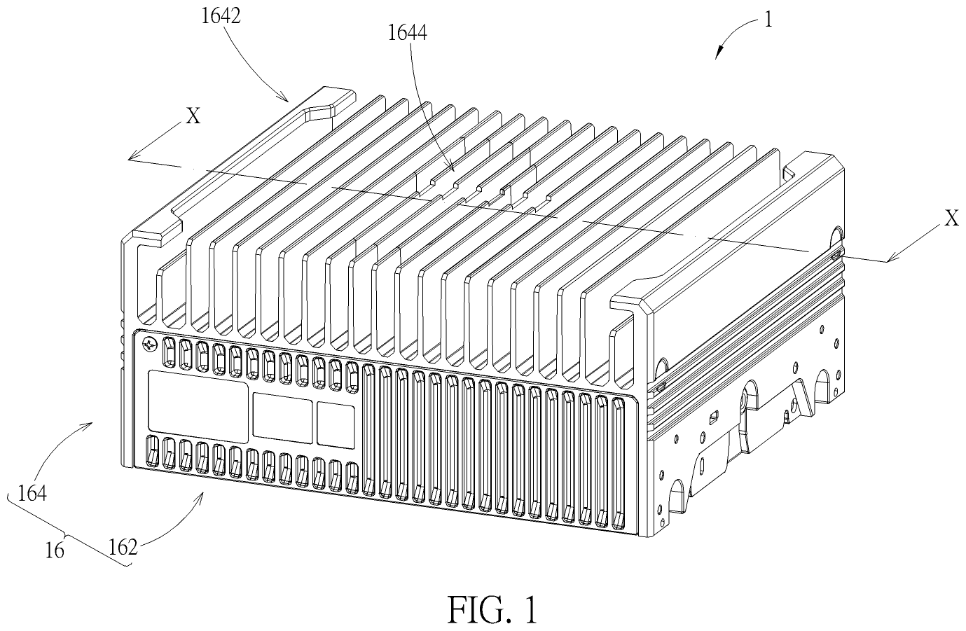

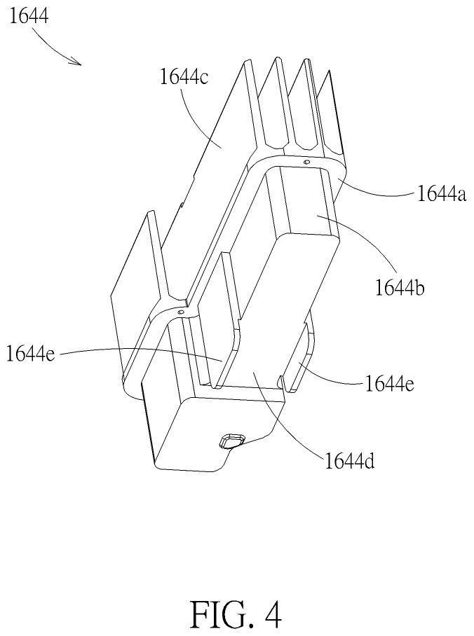

Please refer to FIG. 1 to FIG. 5. An electronic apparatus 1 according to an embodiment includes a first circuit board module 12, a second circuit board module 14, and an electronic apparatus casing 16. The first circuit board module 12 includes a first heat source 122. The second circuit board module 14 includes a second heat source 142. The first heat source 122 and the second heat source 142 are on different levels. The electronic apparatus casing 16 includes a casing base 162 and a combined heat-dissipating structure 164. The combined heat-dissipating structure 164 and the casing base 162 are connected to form an accommodating space 16a. The first circuit board module 12 and the second circuit board module 14 are disposed in the accommodating space 16a. The combined heat-dissipating structure 164 is thermally coupled with the first heat source 122 and the second heat source 142 to dissipate heat from the first heat source 122 and the second heat source 142 respectively. In practice, the electronic apparatus 1 can be but not limited to a server or a computer host. The first circuit board module 12 can be a single circuit board module or a circuit board module combination including an expansion card; so is the second circuit board module 14. The first heat source 122 and the second heat source 142 can be a chip (e.g. CPU, GPU, memory, etc.) or other components (e.g. heat sink directly fixed on a heating element) that will produce or absorb heat when the electronic apparatus 1 is in operation.

In the embodiment, the combined heat-dissipating structure 164 is also used as the appearance part of the electronic apparatus casing and includes a main heat-dissipating structure 1642 and a detachable heat-dissipating structure 1644. The casing base 162 has a front wall 162a, a rear wall 162b, and two side walls 162c between the front wall 162a and the rear wall 162b. The main heat-dissipating structure 1642 includes a first plate portion 1642a, a first heat conduction column 1642b extending downward from the first plate portion 1642a, a plurality of first fins 1642c extending upward from the first plate portion 1642a, and two side walls 1642d extending downward from two opposite side edges of the first plate portion 1642a. The first plate portion 1642a and the two side walls 1642d as a whole shows an n-shaped structure. The first heat conduction column 1642b are located the two side walls 1642d. The combined heat-dissipating structure 164 and the casing base 162 are connected by connecting the main heat-dissipating structure 1642 with the casing base 162. Therein, the two side walls 1642d are connected to the two side walls 162c of the casing base 162 respectively. The main heat-dissipating structure 1642 is in close contact with the front wall 162a and the rear wall 162b. Thereby, the first heat conduction column 1642b is located in the accommodating space 16a. The first heat conduction column 1642b has a first heat-absorbing surface 1642e and is thermally coupled with the first heat source 122 through the first heat-absorbing surface 1642e, so that the first heat conduction column 1642b can absorb heat from the first heat source 122 through the first heat-absorbing surface 1642e, conduct the heat to the first plate portion 1642a, and then dissipate the heat through the first fins 1642c.

Furthermore, the first plate portion 1642a has an opening 1642f that is located at the central portion of the first plate portion 1642a (substantially at the middle between the two side walls 162c). The detachable heat-dissipating structure 1644 includes a second plate portion 1644a, a second heat conduction column 1644b extending downward from the second plate portion 1644a, and a plurality of second fins 1644c extending upward from the second plate portion 1644a. The detachable heat-dissipating structure 1644 is detachably disposed at the opening 1642f through the second plate portion 1644a (e.g. by screwing screws thereon) to be detachably assembled to the main heat-dissipating structure 1642, so that the second heat conduction column 1644b is located in the accommodating space 16a. The second heat conduction column 1644b has a second heat-absorbing surface 1644d and is thermally coupled with the second heat source 142 through the second heat-absorbing surface 1644d, so that the second heat conduction column 1644b can absorb heat from the second heat source 142 through the second heat-absorbing surface 1644d, conduct the heat to the second plate portion 1644a, and then dissipate the heat through the second fins 1644c.

Therefore, the main heat-dissipating structure 1642 and the detachable heat-dissipating structure 1644 have individual heat transfer paths, which can dissipate heat independently. The main heat-dissipating structure 1642 and the detachable heat-dissipating structure 1644 are designed to be separable, which can reduce or eliminate the influence of assembly tolerance on the thermal coupling between the detachable heat-dissipating structure 1644 and the second heat source 142. The assembly tolerance includes the accumulated tolerances due to assembling components (including assembling the first circuit board module 12 and the second circuit board module 14 into the casing base 162, assembling the combined heat-dissipating structure 164 onto the casing base 162), structural deformation caused by the influence of gravity, etc. Furthermore, in practice, when the detachable heat-dissipating structure 1644 is assembled onto the main heat-dissipating structure 1642, the first plate portion 1642a and the second plate portion 1644a are not limited to being completely in close contact. The gap between them can be used to adjust the assembly tolerance. For this case, a firm connection between the first plate portion 1642a and the second plate portion 1644a can be achieved by screwing screws with a fixed torque. Furthermore, the structure separation design also helps to increase the reusability of the main heat dissipation structure 1642 and the detachable heat dissipation structure 1644. For example, the main heat-dissipating structure 1642 can be matched with other detachable heat-dissipating structures to adapt to different electronic component configurations in the electronic apparatus casing 16.

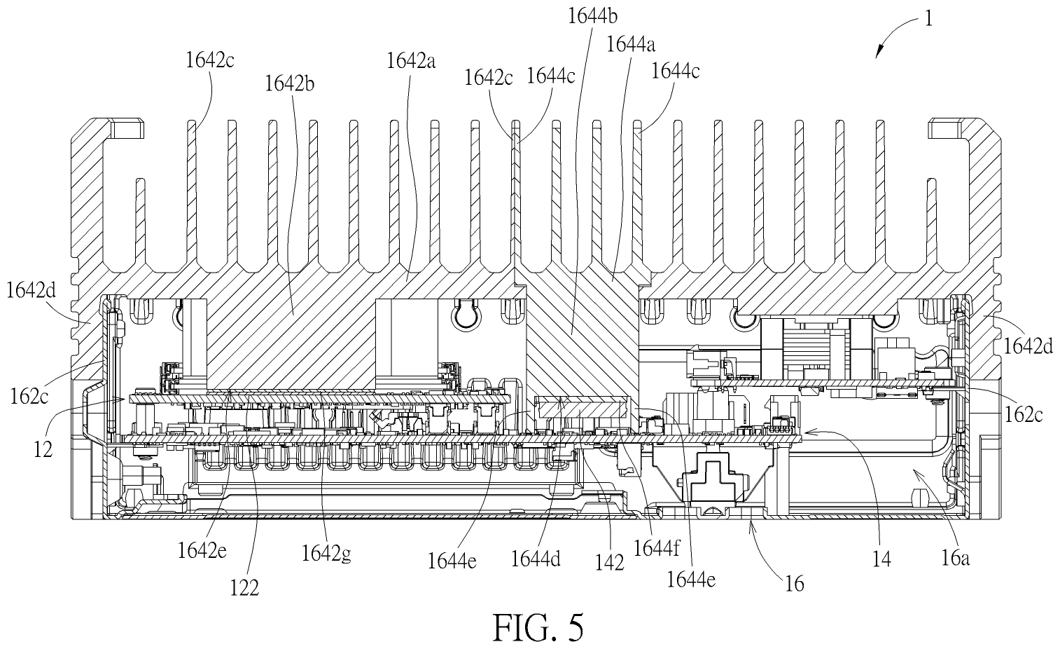

Furthermore, in the embodiment, the second heat conduction column 1644b includes two protruding portions 1644e, which are located at two sides of the second heat-absorbing surface 1644d respectively and protrude from the second heat-absorbing surface 1644d. The second heat source 142 is plugged into the body of the second circuit board module 14 in the form of an expansion card. The two protruding portions 1644e can abut against the second circuit board module 14 carrying the second heat source 142, for avoiding excessive contact force between the second heat-absorbing surface 1644d and the second heat source 142, which may damage the plug-in structure of the expansion card, or even damage the structure of the second heat source 142. Furthermore, a thermal interface material (TIM) 1642g (only shown in FIG. 5, e.g. but not limited to a thermal pad, thermal paste, etc.) is disposed between the first heat-absorbing surface 1642e and the first heat source 122, which can improve the thermal coupling between the first heat-absorbing surface 1642e and the first heat source 122. Similarly, a thermal interface material (TIM) 1644f (e.g. but not limited to a thermal pad, thermal paste, etc.) is disposed between the second heat-absorbing surface 1644d and the second heat source 142, which can improve the thermal coupling between the second heat-absorbing surface 1644d and the second heat source 142.

In addition, in the embodiment, the structural profiles of the a plurality of second fins 1644c and the a plurality of first fins 1642c match with each other, the second plate portion 1644a contours to fit the opening 1642f, so that after the detachable heat-dissipating structure 1644 is assembled to the main heat-dissipating structure 1642, the a plurality of second fins 1644c and the a plurality of first fins 1642c are structurally continuous, and the first plate portion 1642a and the second plate portion 1644a are also structurally continuous. This structural feature helps air flow to flow smoothly through the combined heat-dissipating structure 164.

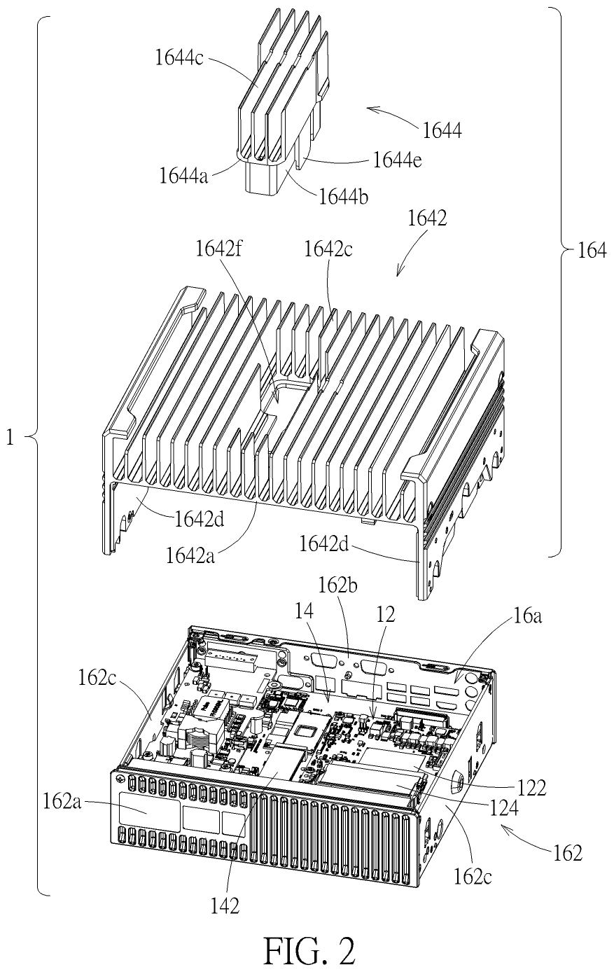

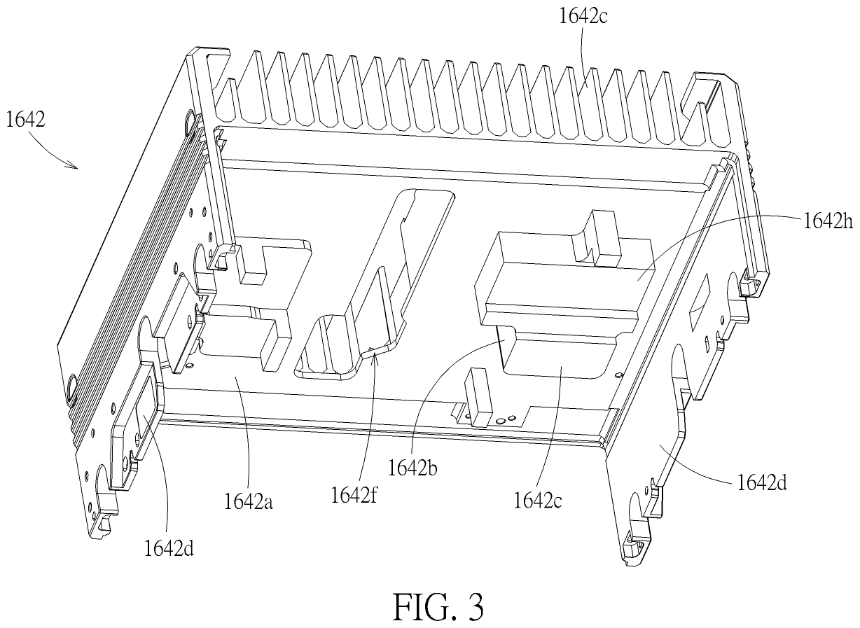

Furthermore, in the embodiment, the main heat-dissipating structure 1642 and the detachable heat-dissipating structure 1644 are formed into a single part individually, e.g. aluminum workpieces; however, it is not limited thereto in practice. For example, the main heat-dissipating structure 1642 or the detachable heat-dissipating structure 1644 can be a composite structure. In addition, as shown by FIG. 2 and FIG. 3, in the embodiment, the main heat-dissipating structure 1642 also includes another heat conduction column 1642h extending downward form the first plate portion 1642a (in which the heat conduction column 1642h and the first heat conduction column 1642b are structurally connected to be a single heat conduction column structure with different heights heat-absorbing surfaces, and still can be regarded as different heat conduction columns logically). The heat conduction column 1642h is thermally coupled with another heat source 124 for dissipating heat from the heat source 124. Similarly, the detachable heat-dissipating structure 1644 also can dissipate heat from multiple heat sources (including the second heat source 142) at the same time, which will not be described. In addition, in the embodiment, the main heat-dissipating structure 1642 and the detachable heat-dissipating structure 1644 dissipate heat from heat sources on different circuit board modules respectively; however, it is not limited thereto in practice. For example, the main heat-dissipating structure 1642 and the detachable heat-dissipating structure 1644 can dissipate heat from different heat sources on the same circuit board module.

In an embodiment according to the invention, the thermal conductivity of the main heat-dissipating structure 1642 and the thermal conductivity of the detachable heat-dissipating structure 1644 may be the same or different. If they are different, the detachable heat-dissipating structure 1644 can be made of material with greater thermal conductivity, e.g. silver, copper, or aluminum and other metal materials with better thermal conductivity.

In an embodiment according to the invention, the electronic apparatus (e.g. server) can be used for artificial intelligence (AI) computing, edge computing, and can also be used as a 5G server, cloud server or car networking server.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A combined heat-dissipating structure, comprising:
a main heat-dissipating structure, comprising a first plate portion, a first heat conduction column extending downward from the first plate portion, and a plurality of first fins extending upward from the first plate portion, the first plate portion having an opening, the first heat conduction column having a first heat-absorbing surface for absorbing heat produced by a heat source; and
a detachable heat-dissipating structure, comprising a second plate portion, a second heat conduction column extending downward from the second plate portion, and a plurality of second fins extending upward from the second plate portion, the second plate portion being detachably disposed at the opening, the second heat conduction column having a second heat-absorbing surface for absorbing heat produced by another heat source.

2. The combined heat-dissipating structure according to claim 1, wherein the second heat conduction column comprises two protruding portions that are located at two sides of the second heat-absorbing surface and protrude the second heat-absorbing surface.

3. The combined heat-dissipating structure according to claim 1, wherein structural profiles of the plurality of second fins and of the plurality of first fins match with each other, the second plate portion contours to fit the opening.

4. The combined heat-dissipating structure according to claim 1, wherein the main heat-dissipating structure comprises two side walls extending downward from two side edges of the first plate portion, and the first heat conduction column and the second heat conduction column are located between the two side walls.

5. The combined heat-dissipating structure according to claim 1, wherein the first heat-absorbing surface and the second heat-absorbing surface absorb heat through a thermal interface material individually.

6. The combined heat-dissipating structure according to claim 1, wherein the main heat-dissipating structure and the detachable heat-dissipating structure are formed into a single part individually.

7. An electronic apparatus casing, comprising:
a casing base; and
a combined heat-dissipating structure, connected to the casing base to form an accommodating space, the combined heat-dissipating structure comprising:
a main heat-dissipating structure, connected to the casing base, the main heat-dissipating structure comprising a first plate portion, a first heat conduction column extending downward from the first plate portion, and a plurality of first fins extending upward from the first plate portion, the first plate portion having an opening, the first heat conduction column being located in the accommodating space and having a first heat-absorbing surface; and
a detachable heat-dissipating structure, comprising a second plate portion, a second heat conduction column extending downward from the second plate portion, and a plurality of second fins extending upward from the second plate portion, the second plate portion being detachably disposed at the opening, the second heat conduction column being located in the accommodating space and having a second heat-absorbing surface.

8. The electronic apparatus casing according to claim 7, wherein the second heat conduction column comprises two protruding portions that are located at two sides of the second heat-absorbing surface and protrude the second heat-absorbing surface.

9. The electronic apparatus casing according to claim 7, wherein structural profiles of the plurality of second fins and of the plurality of first fins match with each other, the second plate portion contours to fit the opening.

10. The electronic apparatus casing according to claim 7, wherein the main heat-dissipating structure comprises two side walls extending downward from two side edges of the first plate portion, and the first heat conduction column and the second heat conduction column are located between the two side walls.

11. The electronic apparatus casing according to claim 7, wherein the first heat-absorbing surface and the second heat-absorbing surface absorb heat through a thermal interface material individually.

12. The electronic apparatus casing according to claim 7, wherein the main heat-dissipating structure and the detachable heat-dissipating structure are formed into a single part individually.

13. An electronic apparatus, comprising:
a first heat source;
a second heat source; and
an electronic apparatus casing, comprising:
a casing base; and
a combined heat-dissipating structure, connected to the casing base to form an accommodating space, the first heat source and the second heat source being disposed in the accommodating space, the combined heat-dissipating structure comprising:
a main heat-dissipating structure, connected to the casing base, the main heat-dissipating structure comprising a first plate portion, a first heat conduction column extending downward from the first plate portion, and a plurality of first fins extending upward from the first plate portion, the first plate portion having an opening, the first heat conduction column being located in the accommodating space and having a first heat-absorbing surface, the first heat conduction column being thermally coupled with the first heat source through the first heat-absorbing surface; and
a detachable heat-dissipating structure, comprising a second plate portion, a second heat conduction column extending downward from the second plate portion, and a plurality of second fins extending upward from the second plate portion, the second plate portion being detachably disposed at the opening, the second heat conduction column being located in the accommodating space and having a second heat-absorbing surface, the second heat conduction column being thermally coupled with the second heat source through the second heat-absorbing surface.

14. The electronic apparatus according to claim 13, further comprising a first circuit board module and a second circuit board module, disposed in the accommodating space, wherein the first heat source and the second heat source are disposed on the first circuit board module and the second circuit board module respectively.

15. The electronic apparatus according to claim 13, wherein the second heat conduction column comprises two protruding portions that are located at two sides of the second heat-absorbing surface and protrude the second heat-absorbing surface.

16. The electronic apparatus according to claim 13, wherein structural profiles of the plurality of second fins and of the plurality of first fins match with each other, the second plate portion contours to fit the opening.

17. The electronic apparatus according to claim 13, wherein the main heat-dissipating structure comprises two side walls extending downward from two side edges of the first plate portion, and the first heat conduction column and the second heat conduction column are located between the two side walls.

18. The electronic apparatus according to claim 13, wherein the first heat-absorbing surface and the second heat-absorbing surface absorb heat through a thermal interface material individually.

19. The electronic apparatus according to claim 13, wherein the main heat-dissipating structure and the detachable heat-dissipating structure are formed into a single part individually.
